(19) United States
(12) Patent Application Publication
(10) Pub. No.: US 2008/0211486 A1
(43) Pub. Date: Sep. 4, 2008

(54) AUTO-HANDLER COMPRISING PUSHERS EACH INCLUDING PELTIER DEVICE

(75) Inventors: Eiji MORIYAMA, Tokyo (JP); Masayuki Takahashi, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: Elpida Memory, Inc., Tokyo (JP)

(21) Appl. No.: 11/965,324

(22) Filed: Dec. 27, 2007

(30) Foreign Application Priority Data
Jan. 9, 2007 (JP) 2007-001388

(51) Int. Cl. G01R 1/04; G01K 13/00; G01R 31/26

(52) U.S. Cl. 324/158.1; 374/142; 374/E13.001

(57) ABSTRACT

In an auto-handler for use in conjunction with an IC tester including a plurality of sockets in which a plurality of target devices are inserted, the auto-handler includes a plurality of pushers corresponding to the plurality of sockets and a plurality of temperature sensors for detecting temperatures of the plurality of target devices. Each pusher is mounted on a heat sink via a Peltier device. Each Peltier device and each temperature sensor are connected to a current controlling apparatus. The current controlling apparatus controls, on the basis of an output of each temperature sensor, a current supplied to the corresponding Peltier device. Accordingly, it is possible to individually control temperatures of the plurality of target devices with accuracy.

This application is based upon and claims the benefit of priority from Japanese patent application No. 2007-001388, filed on Jan. 9, 2007, the disclosure of which is incorporated herein in its entirety by reference.

### BACKGROUND OF THE INVENTION

This invention relates to an auto-handler for use in conjunction with an integrated circuit (IC) tester for carrying out functional tests of a plurality of semiconductor devices.

The auto-handler is connected to the IC tester for carrying out the functional tests of the semiconductor devices. The auto-handler acts as a pushing and pulling-out arrangement of the semiconductor devices (which will later be referred to as “target devices” or “objective devices”) serving as targets or objects for the test in conjunction with the IC tester. Specifically, the auto-handler first inserts a plurality of target devices held in a transfer board in respective sockets of the IC tester in collective manner, pulls out the target devices from the sockets after end of the test by the IC tester, and carries out screening the target devices on the basis of test results of the IC tester. In addition, the auto-hander provides environment of a test temperature between about −30° C. and +90° C.

In the manner which will later be described in conjunction with FIGS. 1 and 2, a related auto-handler controls a temperature in a chamber bath in collective manner. As a result, the related auto-handler is disadvantageous in a time interval consumes to reach a set temperature, there is a large difference between the set temperature and temperatures of the target devices, there are temperature differences (variation) between the target devices, and so on.

Hence, in order to resolve their problems, Japanese Unexamined Patent Application Publication of Tokkai No. Hei 7-27,819 or JP-A 7-27819 (which will later be called a patent document 1) discloses a carrier board having heating, cooling and heat keeping functions. The carrier board disclosed in the patent document 1 comprises a heat-insulating box disposed on one surface thereof. The heat-insulating box comprises a heat-insulating frame and a heat-insulating door reclosably mounted on the heat-insulating frame. A lower thermal-conductivity block is mounted on the carrier board in the heat-insulating box while an upper thermal-conductivity block is mounted on the heat-insulating door. In addition, the lower thermal-conductivity block and the upper thermal-conductivity block are provided with heaters or the like, respectively. The lower thermal-conductivity block is provided with a plurality of sockets for receiving the target devices so as to sandwich the target devices between the lower thermal-conductivity block and the upper thermal-conductivity block when the heat-insulating door is closed. In addition, the patent document 1 also discloses the carrier board comprising upper and lower Peltier elements.

Inasmuch as the carrier board heats and cools the target devices via the lower thermal-conductivity block and the upper thermal-conductivity block, it is possible to set temperatures of the target devices in a set temperature at a short time in compassion with a case of controlling the temperature in the chamber bath. In addition, a difference between the set temperature and the temperature of the target device is small. Furthermore, inasmuch as temperature control can be carried out per thermal-conductivity block, it is possible to keep variation between the target devices small.

However, the carrier board is disadvantageous in that it is complicated in structure and a high cost because the carrier board is provided with thermal-conductivity blocks and heating and cooling means up and down of the target device. This disadvantage is especially remarkable in a system where a plurality of carrier boards are circulated. In addition, the carrier board is also disadvantageous in that work is complicated to require a long time duration because it is necessary to open and close the heat-insulating box in order to mount/pull the target devices on/out. Furthermore, the carrier board is disadvantageous in that it is impossible to use a functional test of a ball grid array (BGA) which is currently the mainstream of a package because heating is carried out to the target devices up and down thereof.

Although technique related to the auto-handler is not disclosed, Japanese Unexamined Patent Application Publication of Tokkai No. Hei 1-286,322 or JP-A 1-286322 (which will later be called a patent document 2) discloses, as technique of absorbing self heat generation of a target device during a functional test, a method of causing the target device come into contact with a metallic block bonded to a Peltier element or device.

However, the patent document 2 neither discloses nor teaches description related to the auto-handler, description of preparing test temperature environmental, description of concurrently testing a plurality of target devices.

### SUMMARY OF THE INVENTION

It is an exemplary object of this invention to provide an auto-handler which is capable of quickly changing temperatures of target devices up to a set temperature with high accuracy.

It is another exemplary object of this invention to provide an auto-handler at relatively low cost.

Other exemplary objects of this invention will become clear as the description proceeds.

According to an exemplary aspect of this invention, an auto-handler is for use in conjunction with an integrated circuit (IC) tester comprising first through N-th sockets, where N represents a positive integer which is not less than two. The IC tester carries out functional tests of first through N-th target devices inserted in the first through the N-th sockets, respectively. The auto-handler comprises first through N-th pushers corresponding to the first through the N-th sockets, respectively. The first through the N-th pushers push the first through the N-th target devices so as to insert the first through the N-th target devices in the first through the N-th sockets, respectively. Coupled to the first through the N-th pushers, a temperature regulating mechanism for individually controls temperatures of the first through the N-th target devices so as to maintain first through N-th set temperatures, respectively.

### BRIEF DESCRIPTION OF THE DRAWINGS

FIG. 1 is an exploded perspective view of a related auto-handler;

FIG. 2 is a partially sectional view of the related auto-handler illustrated in FIG. 1;

FIG. 3 is a partially exploded perspective view of an auto-handler according a first exemplary embodiment of this invention;

FIG. 4 is a partially sectional view of the auto-handler illustrated in FIG. 3;

FIG. 5 is a bock diagram of a temperature regulating mechanism for use in the auto-handler illustrated in FIG. 3;

FIG. 6 is a partially sectional view of an auto-handler according a second exemplary embodiment of this invention;

FIG. 7 is a partially sectional view of an auto-handler according a third exemplary embodiment of this invention; and

FIG. 8 is a partially sectional view of an auto-handler according a fourth exemplary embodiment of this invention.

### DESCRIPTION OF THE EXEMPLARY EMBODIMENTS

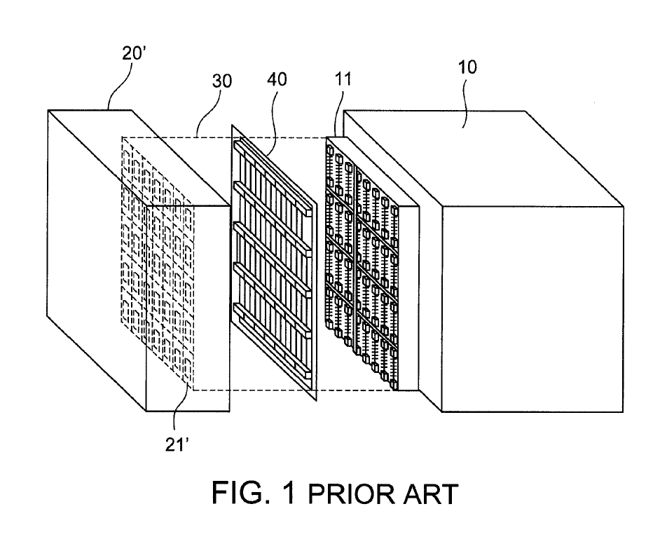

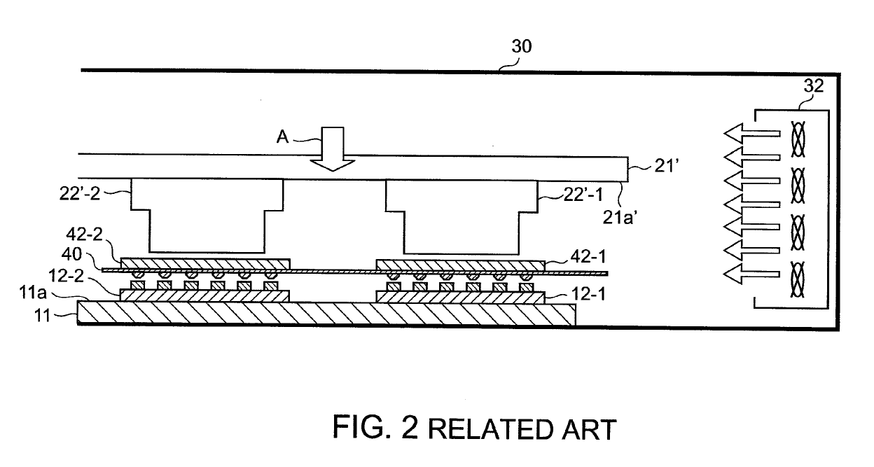

Referring to FIGS. 1 and 2, a related auto-handler 20′ will be described at first in order to facilitate an understanding of the present invention. FIG. 1 is an exploded perspective view of the related auto-handler 20′. FIG. 2 is a partially sectional view of the related auto-handler 20′.

The auto-handler 20′ is for use in conjunction with an integrated circuit (IC) tester 10. The IC tester 10 comprises a test board 11 having a principal surface 11a on which first through N-th sockets 11-1 to 11-N are mounted or arranged, where N represents a predetermined positive integer which is not less than two. The test board 11 is also called a socket board. The first and the second sockets 11-1 and 11-2 are illustrated alone in FIG. 2.

The auto-handler 20′ comprises a pusher board 21′ disposed so as to be opposed to the socket board 11 of the IC tester 10, as shown in FIG. 1. The pusher board 21′ has a principal surface 21′a on which first through N-th pushers 22′-1 to 22′-N are mounted. The first and the second pushers 22′-1 and 22′-2 alone are illustrated in FIG. 2. As shown in FIG. 2, the first through the N-th pushers 22′-1 to 22′-N are opposite to the first through the N-th sockets 12-1 to 12-N, respectively. Between the pusher board 21′ and the socket board 11, a chamber both 30 is disposed. The chamber bath 30 is for forming a temperature-regulating space between the pusher board 21′ and the socket board 11.

A transfer board 40 is transferred between the socket board 11 and the pusher board 21′ and is accommodated in the chamber bath 30. As shown in FIG. 2, on the transfer board 40, first through N-th target devices 42-1 to 42-N are held. The first and the second target devices 42-1 and 42-2 alone are illustrated in FIG. 2. The first through the N-th target devices 42-1 to 42-N are pushed by the first through the N-th pushers 22′-1 to 22′-N in a direction depicted at an arrow A of FIG. 2 and are inserted in the first through the N-th sockets 12-1 to 12-N, respectively.

The chamber both 30 comprises an electric heater 32 therein that enables to heat the first through the N-th target devices 42-1 to 42-N in collective manner. In addition, the chamber both 30 is coupled to a gas infusion and exhaust equipment (not shown) which enables to cool the first through the N-th target devices 42-1 to 42-N in collective manner by infusing cooled air obtained by cooling air, for example, liquid nitrogen. In the manner which is described above, it is possible to prepare test temperature environment in the chamber both 30.

However, inasmuch as the related auto-handler 20′ controls temperature in the chamber bath 30 in collective manner. As a result, the related auto-handler 20′ is disadvantageous in a time interval consumes to reach a set temperature, there is a large difference between the set temperature and temperatures of the first through the N-th target devices 42-1 to 42-N, there are temperature differences (variation) between the first through the N-th target devices 42-1 to 42-N, and so on, as mentioned in the preamble of the instant specification.

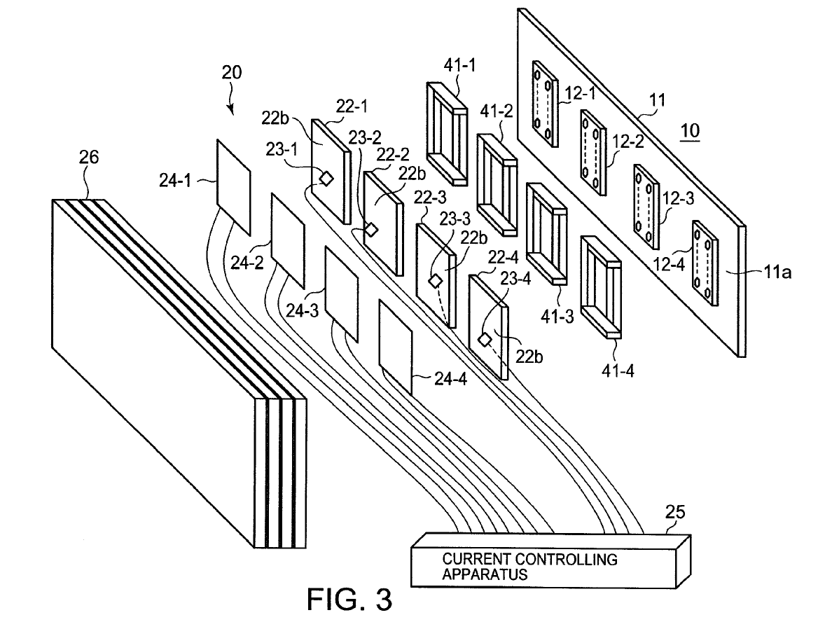

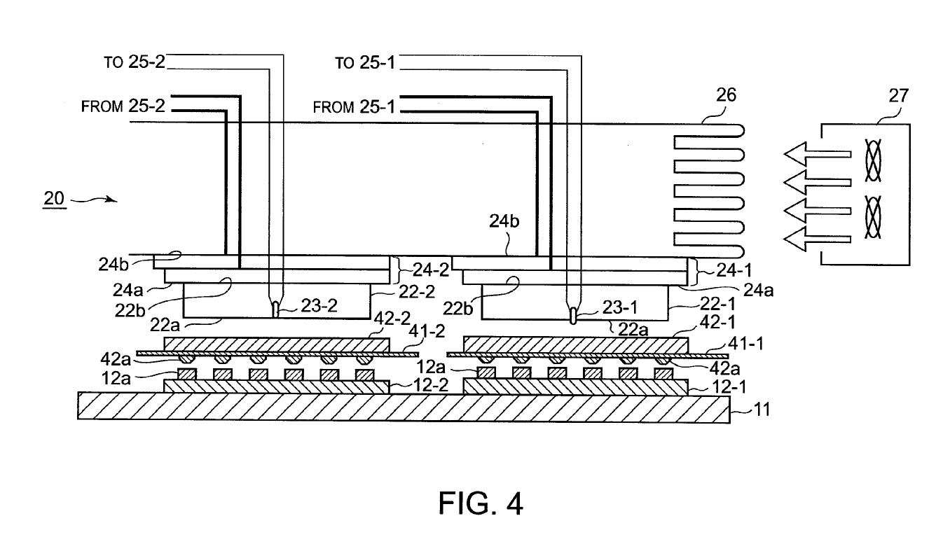

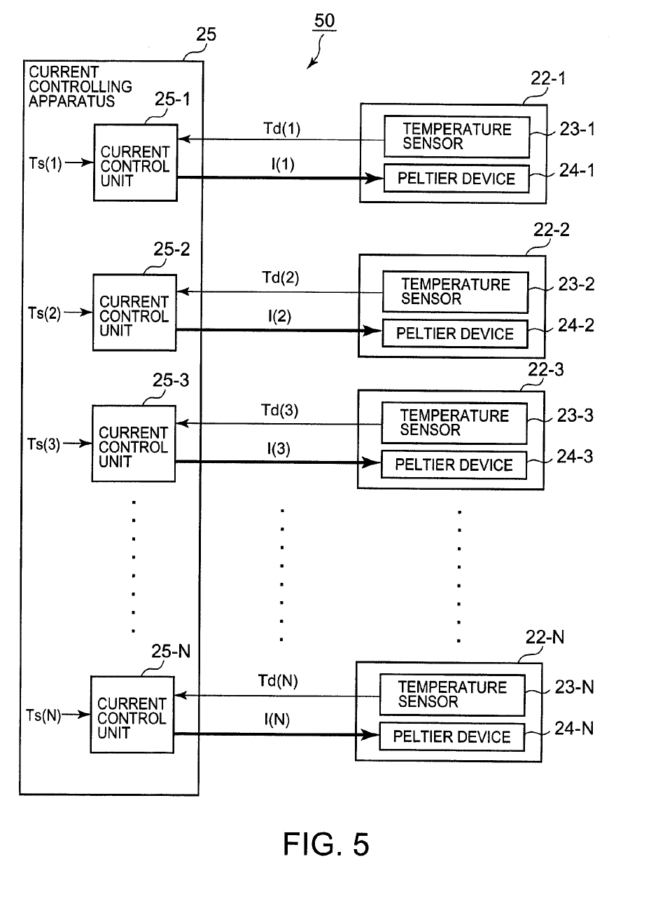

Referring to FIGS. 3 through 5, the description will proceed to an auto-handler 20 according to a first exemplary embodiment of this invention. FIG. 3 is a partially exploded perspective view of the auto-handler 20. FIG. 4 is a partially cross sectional view of the auto-handler 20. FIG. 5 is a block diagram of a temperature regulating mechanism 50 for use in the auto-handler 20.

The illustrated auto-handler 20 is for use in conjunction with the integrated circuit (IC) tester 10 (see FIG. 1). The IC tester 10 comprises the socket board 11 having the principal surface 11a on which the first through the N-th sockets 12-1 to 12-N are mounted and arranged, where N represents the predetermined positive integer which is not less than two. Although the positive integer N is equal to four in FIG. 3 and two in FIG. 4, the positive integer N is normally equal to sixty-four or two hundred and fifty-six when each target device comprises a dynamic random access memory (DRAM). The IC tester 10 carries out functional tests of the first through the N-th target devices 42-1 to 42-N inserted in the first through the N-th sockets 12-1 to 12-N, respectively. The first through the N-th target devices 42-1 to 42-N are held in first through N-th transfer carriers 41-1 to 41-N, respectively.

The auto-handler 20 comprises first through N-th pushers 22-1 to 20-N corresponding to the first through the N-th sockets 12-1 to 12-N, respectively. In the manner which will later be described, the first through the N-th pushers 22-1 to 22-N push the first through the N-th target devices 42-1 to 42-N so as to insert the first through the N-th target devices 42-1 to 42-N in the first through the N-th sockets 12-1 to 12-N, respectively. Each of the first though the N-th pushers 22-1 to 22-N is made of material having high thermal conductivity such as metal.

The first through the N-th pushers 22-1 to 22-N have front surfaces 22a in contact with the first through the N-th target devices 42-1 to 42-N, respectively, when the first through the N-th target devices 42-1 to 42-N are inserted in the first through the N-th sockets 12-1 to 12-N, respectively. The first through the N-th pushers 22-1 to 22-N have rear surfaces 22b opposed to the front surfaces 22a.

The auto-handler 20 further comprises the temperature regulating mechanism 50 as shown in FIG. 5. In the manner which will later be described, the temperature regulating mechanism 50 individually controls temperatures of the first though the N-th target devices 42-1 to 42-N so as to maintain first through N-th set temperatures Ts(1) to Ts(N), respectively.

Specifically, the temperature regulating mechanism 50 comprises first through N-th temperature sensors 23-1 to 23-N, first through N-th Peltier devices or elements 24-1 to 24-N, and a current control apparatus 25. The current control apparatus 25 comprises first through N-th current control units 25-1 to 25-N.

The first through the N-th temperature sensors 23-1 to 23-N are mounted on the front surfaces 22a of the first through the N-th pushers 22-1 to 22-N, respectively. The first through the N-th temperature sensors 23-1 to 23-N detect the temperatures of the first through the N-th target devices 42-1 to 42-N to produce first through N-th detected signals indicative of first through N-th detected temperatures Td(1) to Td(N), respectively. More specifically, an n-th temperature sensor 23-n is disposed on the front surface 22a of an n-th pusher 22-n so as to exposure from the front surface 22a thereof, where n represents a variable between 1 and N, both inclusive. Alternatively, the n-th temperature sensor 23-n may be disposed on the front surface 22a of the n-th pusher 22-n so as to being in contact with the front surface 22a thereof. That is, the n-th temperature sensor 23-n is disposed in the immediate vicinity of an n-th target device 42-n held in an n-th transfer carrier 41-n.

The first through the N-th Peltier devices 24-1 to 24-N are mounted on the rear surfaces 22a of the first through the N-th pushers 22-1 to 22-N, respectively. In the manner which is well known in the art, an n-th Peltier device 24-n is a plate-shaped electronic device which can cause a temperature difference generate both sides thereof. The temperature difference between the both sides of the n-th Peltier device 24-n is generated by applying an n-th current I(n) to the n-th Peltier device 24-n. The n-th Peltier device 24-n quickly responds in response to a current value applied thereto.

The first through the N-th Peltier devices 24-1 to 24-N have front surfaces 24a on which the first through the N-th pushers 22-1 to 22-N are mounted, respectively. The first through the N-th Peltier devices 24-1 to 24-N have rear surfaces 24b opposed to the front surfaces 24b thereof.

The first through the N-th pushers 22-1 to 22-N are mounted on a heat sink 26 via the first through the N-th Peltier devices 24-1 to 24-N in common. In other words, mounted on the first through the N-th pushers 22-1 to 22-N, the first through the N-th Peltier devices 24-1 to 24-N are fixed to the heat sink 26 at the rear surfaces 24b thereof in common.

As shown in FIG. 5, the first through the N-th temperature sensors 22-1 to 22-N and the first through the N-th Peltier devices 24-1 to 24-N are connected to the current control apparatus 25. Specifically, the n-th temperature sensor 22-n and the n-th Peltier device 24-n are connected to an n-th current control unit 25-n. The n-th current control unit 25-n is supplied with an n-tu set command indicative of an n-th set temperature Ts(n). The n-th current control unit 25-n controls, on the basis of the n-th detected signal indicative of the n-th detected temperature Td(n), an n-th current I(n) supplied to the n-th Peltier device 24-n so that the n-th detected temperature Td(n) is equal to an n-th set temperature Ts(n).

As shown in FIG. 4, the auto-handler 20 further comprises an air blower 27 for blowing air into the heat sink 26 to accelerate heat radiation.

Referring to FIGS. 3 through 5, description will be made as regards operation of the auto-handler 20.

A transfer mechanism (not shown) transfers the first through the N-th target devices 42-1 to 42-N held in the first through the N-th transfer carriers 41-1 to 41-N between the first through the N-th sockets 12-1 to 12-N and the first through the N-th pushers 22-1 to 22-N. Subsequently, a driving mechanism (not shown) drives the first through the N-th pushers 22-1 to 22-N together with the heat sink 26 toward the first through the N-th sockets 12-1 to 12-N, respectively. Therefore, the first through the N-th pushers 22-1 to 22-N collide with the first through the N-th target devices 42-1 to 42-N, respectively, to push the first through the N-th the target devices 42-1 to 42-N so as to insert the first through the N-th target devices 42-1 to 42-N in the first through the N-th sockets, respectively. In the example being illustrated, each of the first through the N-th sockets 12-1 to 12-N has a plurality of contact terminals 12a while each of the first through the N-th target devices 42-1 to 42-N has a plurality of terminals 42a. In this event, the terminals 42a of the n-th target device 42-n are pushed and are in contact with the corresponding contact terminals 12a of the n-th socket 12-n.

Subsequently, the first through the N-th current control units 25-1 to 25-N supply the first through the N-th Peltier devices 24-1 to 24-N with the first through the N-th currents I(1) to I(N), respectively. Supply of the first through the N-th currents I(1) to I(N) may start before driving the first through the N-th pushers 22-1 to 22-N. When the first through the N-th currents I(1) to I(N) are supplied to the first through the N-th Peltier devices 24-1 to 24-N, respectively, the temperature differences generate the both sides of the first through the N-th Peltier devices 24-1 to 24-N. In this event, a temperature of the heat sink 26 serves as a base temperature for causing temperatures of the front surfaces 24a of the first through the N-th Peltier devices 24-1 to 24-N change to the first through the N-th set temperatures Ts(1) to Ts(N), respectively. It will be assumed that the temperature of the heat sink 26 is constant. In this event, the temperature of the front surface 24a of the n-th Peltier device 24-n becomes the sum of the temperature of the heat sink 26 and the temperature difference between the both sides of the n-th Peltier device 24-n.

Inasmuch as the n-th pusher 22-n is made of the material having high thermal conductivity such as metal, the n-th pusher 22-n follows a change of temperature when the temperature of the n-th Peltier device 24-n changes. Accordingly, when the n-th Peltier device 24-n is in contact with the n-th target device 42-n, a change of the temperature of the n-th Peltier device 24-n is immediately transmitted to the n-th target device 42-n.

Inasmuch as the n-th temperature sensor 23-n is in contact with the n-th target device 42-n or is positioned extremely near to the target device 42-n, the n-th temperature sensor 23-n detects the temperature of the n-th target device 42-n or the temperature of the n-th pusher 22-n that is substantially equal to the temperature of the n-th target device 42-n. The n-th temperature sensor 23-n produces the n-th detected signal indicative of the n-th detected temperature Td(n) which is fed back to the n-th current control unit 25-n.

On the basis of the n-th detected signal indicative of the n-th detected temperature Td(n), the n-th current control unit 25-n supplies the n-th Peltier device 24-n with the n-th current I(n) so that temperature of the n-th target device 42-n (the n-th detected temperature Td(n)) is equal to the n-th set temperature Ts(n) which is predetermined set.

In addition, the heat sink 26 plays a role in absorbing heat which generates incident to the controlling the temperatures of the first through the N-th target devices 42-1 to 42-N (and the first through the N-th pushers 22-1 to 22-N). It is therefore necessary for the heat sink 26 to have a large heat capacity and to maintain a stable temperature to some extent. However, high precision is not required to the heat sink 26. This is because it is possible to control the temperature of the n-th target device 42-n (the n-th pusher 22-n) with high precision by individually controlling the n-th current I(n) supplied to the n-th Peltier device 24-n.

For example, it will be assumed that the temperature of the heat sink 26 is kept at about 20° C. and an environmental temperature (or a set temperature) in an IC test is 80° C. In addition, it will be assumed that temperature of the rear surface 24b of the n-th Peltier device 24-n is 14° C. Under the circumstances, the n-th current I(n) supplied to the n-th Peltier device 24-n is controlled on the basis of the n-th detected signal from the n-th temperature sensor 23-n and results in the temperature difference of the both sides of the n-th Peltier device 24-n being 66° C. Accordingly, it is possible to make the temperature of the n-th target device 42-n 80° C. In addition, it will be assumed that the temperature of the rear surface 24b of the n-th Peltier device 24-n changes from 14° C. to 16° C. after that. In this event, the n-th current I(n) supplied to the n-th Peltier device 24-n is controlled in the similar manner which is described above and results in the temperature difference of the both sides of the n-th Peltier device 24-n being 64° C. Therefore, the temperature of the n-th target device 42-n is kept to the n-th set temperature Ts(n).

In the manner which is described above, inasmuch as the auto-handler 20 carries out temperature control of the first through the N-th target devices 42-1 to 42-N, individually, it is possible to decrease the unevenness in the temperatures of the first through the N-th target devices 42-1 to 42-N within ±1° C. In addition, inasmuch as the first through the N-th Peltier devices 24-1 to 24-N each of which is quick-response are used and targets for controlling temperature (the first through the N-th pushers 22-1 to 22-N and the first through the N-th target devices 42-1 to 42-N) are small, a time interval elapsed while the temperatures of the first through the N-th target devices 42-1 to 42-N reach the first through the N-th set temperatures Ts(1) to Ts(N) is short about two minutes or less. Furthermore, inasmuch as the first through the N-th temperature sensors 23-1 to 23-N are disposed in the immediate vicinity of the first through the N-th target devices 42-1 to 42-N, respectively, it is possible to carry out temperature control with high precision having a small error of about 0 to 2° C. Inasmuch as the auto-handler 20 carries out heating of the first through the N-th target devices 42-1 to 42-N by the first through the N-th pushers 221- to 22-N at one side (upper side) thereof, the auto-handler 20 can be used to test, as the target devices, the BGA packages which are difficult to heat from another sides (lower sides) thereof.

In addition, the auto-handler 20 is low cost because heating mechanisms or the like are not disposed in respective carrier boards. Moreover, the auto-handler 20 is simple in structure and inexpensive in comparison with the carrier board comprising the heat-insulating box. In addition, the auto-handler 20 can use, as the first through the N-th transfer carriers 41-1 to 41-N, general carrier boards, opening/closing operation of the heat-insulation box is not required, process thereof is simple, and it is possible to decrease a factor of a non-operation time of a system.

Inasmuch as the auto-hander 20 has characteristics described above, the auto-hander 20 is responsive to temperature and is suitable to screen the DRAMs in which a cost-cutting demand increases markedly.

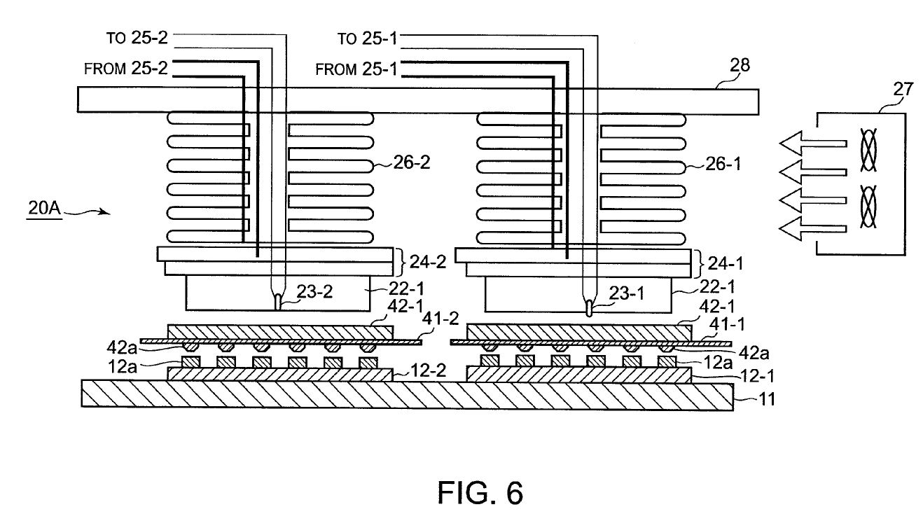

Referring to FIG. 6, the description will proceed to an auto-handler 20A according to a second exemplary embodiment of this invention. The auto-hander 20A is similar in structure and operation to the auto-hander 20 illustrated in FIGS. 3 and 4 except that the auto-handler 20A comprises first through N-th heat sinks 26-1 to 26-N and a heat exchanger plate 28 in lieu of the heat sink 26. The first and the second heat sinks 26-1 and 26-N alone are illustrated in FIG. 6.

The first through the N-th heat sinks 26-1 to 26-N are mounted on the heat exchanger plate 28 in common. The first through the N-th heat sinks 26-1 to 26-N are mounted to the first through the N-th pushers 22-1 to 22-N via the first through the N-th Peltier devices 24-1 to 24-N, respectively.

Although the auto-handler 20A comprises only one air blower 27 for blowing air into the first through the N-th heat sinks 26-1 to 26-N, the auto-hander 20A may comprise first through N-th air blowers for blowing air into the first through the N-th heat sinks 26-1 to 26-N, respectively.

Although the auto-handler 20A comprises the first through the N-th heat sinks 26-1 to 26-N, the auto-handler 20A may comprise first through M-th heat sinks, where M represents a second predetermined positive integer which is not less than two and which is less than N, namely, 2≦M<N. In this event, one or more Peltier devices are mounted on each heat sink.

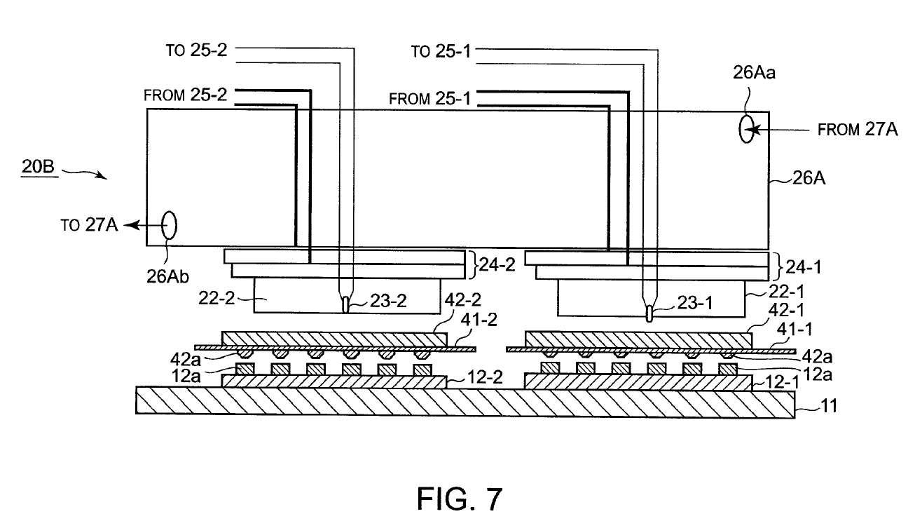

Referring to FIG. 7, the description will proceed to an auto-handler 20B according to a third exemplary embodiment of this invention. The auto-hander 20B is similar in structure and operation to the auto-hander 20 illustrated in FIGS. 3 and 4 except that the auto-handler 20B comprises a water cooled head 26A and a cooling water circulating device 27A (not shown) in lieu of the heat sink 26 and the air blower 27.

The water cooled head 26A has an inlet 26Aa and an outlet 26Ab. The water cooled head 26A is mounted on the first through the N-th pushers 22-1 to 22-N via the first through the N-th Peltier devices 24-1 to 24-N in common. The cooling water circulating device 27A is coupled to the inlet 26Aa and the outlet 26Ab of the water cooled head 26A. The cooling water circulating device 27A supplies cooling water to the inlet 26Aa of the water cooled head 26A and recovers processed water from the outlet 26Ab of the water cooled head 26A. That is, the cooling water circulating device 27A circulates the cooling water through the water cooled head 26A.

The auto-handler 20B is simple in structure as similar to the auto-handler 20. It is possible for the auto-handler 20B to control the temperatures of the first through the N-th target devices 42-1 to 42-N at a high speed and with high precision.

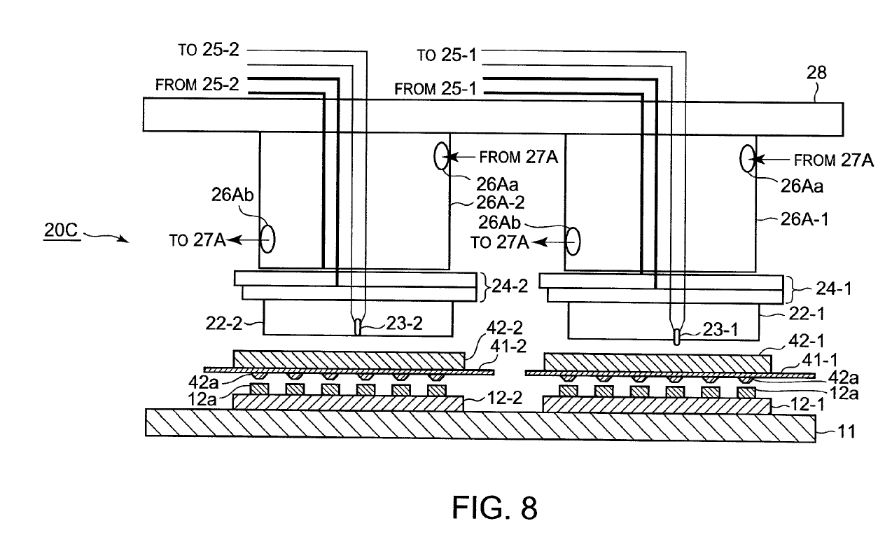

Referring to FIG. 8, the description will proceed to an auto-handler 20C according to a fourth exemplary embodiment of this invention. The auto-handler 20C is similar in structure and operation to the auto-handler 20B illustrated in FIG. 7 except that the auto-handler 20C comprises first through N-th water cooled head 26A-1 to 26A-N and the heat exchanger plate 28 in lieu of the water cooled head 26A. The first and the second water cooled heads 26A-1 and 26A-N alone are illustrated in FIG. 8.

The first through the N-th water cooled heads 26A-1 to 26A-N are mounted on the heat exchanger plate 28 in common. The first through the N-th water cooled heads 26A-1 to 26A-N are mounted to the first through the N-th pushers 22-1 to 22-N via the first through the N-th Peltier devices 24-1 to 24-N, respectively.

Each of the first through the N-th water cooled heads 26A-1 to 26A-N has the inlet 26Aa and the outlet 26Ab. The cooling water circulating device 27A is coupled to the inlets 26Aa and the outlets 26Ab of the first through the N-th water cooled heads 26A-1 to 26A-N.

Although the auto-handler 20C comprises only one cooling water circulating device 27A for circulating cooling water through the first through the N-th water cooled heads 26A-1 to 26A-N, the auto-hander 20C may comprise first through N-th cooling water circulating devices for circulating cooling water through the first through the N-th water cooled heads 26A-1 to 26A-N, respectively.

Although the auto-handler 20C comprises the first through the N-th water cooled heads 26A-1 to 26A-N, the auto-handler 20C may comprise first through M-th water cooled heads. In this event, one or more Peltier devices are mounted on each water cooled head.

While this invention has been particularly shown and described with reference to exemplary embodiments thereof, the invention is not limited to these embodiments. It will be understood by those of ordinary skill in the art that various changes in form and details may be therein without departing from the sprit and scope of the present invention as defined by the claims.

What is claimed is:

1. An auto-handler for use in conjunction with an integrated circuit (IC) tester comprising first through N-th sockets, where N represents a positive integer which is not less than two, said IC tester carrying out functional tests of first through N-th target devices inserted in said first through said N-th sockets, respectively, said auto-handler comprising:
first through N-th pushers corresponding to said first through said N-th sockets, respectively, said first through said N-th pushers pushing said first through said N-th target devices so as to insert said first through said N-th target devices in said first through said N-th sockets, respectively; and
a temperature regulating mechanism, coupled to said first through said N-th pushers, for individually controlling temperatures of said first through said N-th target devices so as to maintain first through N-th set temperatures, respectively.

2. The auto-handler as claimed in claim 1, said first through said N-th pushers having front surfaces in contact with said first through said N-th target devices when said first through said N-th target devices are inserted in said first through said N-th sockets, respectively, said first through said N-th pushers having rear surfaces opposed to the front surfaces, wherein said temperature regulating mechanism comprises:
first through N-th temperature sensors, mounted on the front surfaces of said first through said N-th pushers, for detecting temperatures of said first through said N-th target devices to produce first through N-th detected signals indicative of first through N-th detected temperatures, respectively;
first through N-th Peltier devices mounted on the rear surfaces of said first through said N-th pushers, respectively; and
first through N-th current control units for controlling, on the basis of the first through the N-th detected signals, first through N-th currents supplied to said first through said N-th Peltier devices so that the first through the N-th detected temperatures are equal to the first through the N-th set temperatures, respectively.

3. The auto-handler as claimed in claim 2, wherein said first through said N-th temperature sensors are disposed on the front surfaces of said first through said N-th pushers so as to exposure from the front surfaces thereof.

4. The auto-handler as claimed in claim 2, wherein further comprises a heat sink on which said first through said N-th pushers are mounted via said first through said N-th Peltier devices in common.

5. The auto-handler as claimed in claim 4, wherein further comprises an air blower for blowing air into said heat sink.

6. The auto-handler as claimed in claim 2, wherein further comprises first through N-th heat sinks on which said first through said N-th pushers are mounted via said first through said N-th Peltier devices, respectively.

7. The auto-handler as claimed in claim 6, wherein further comprises an air blower for blowing air into said first through said N-th heat sinks.

8. The auto-handler as claimed in claim 2, wherein further comprises a water-cooled head on which said first through said N-th pushers are mounted via said first through said N-th Peltier devices in common.

9. The auto-handler as claimed in claim 2, wherein further comprises first through N-th water cooled heads on which said first through said N-th pushers are mounted via said first through said N-th Peltier devices, respectively.

10. A method of controlling temperatures of first through N-th target devices, where N represents a positive integer which is not less than two, said method comprising:
pushing said first through said N-th target devices by first through N-th pushers, respectively, so as to insert said first through said N-th target devices in first through N-th sockets of an integrated circuit (IC) tester, respectively; and
individually controlling the temperatures of said first through said N-th target devices so as to maintain first through N-th set temperatures, respectively.

11. The method as claimed in claim 10, wherein said individually controlling the temperatures of said first through said N-th target devices comprising:
detecting the temperatures of said first through said N-th target devices to produce first through N-th detected signals indicative of first through N-th detected temperatures; and
controlling, on the basis of the first through the N-th detected signals, first through N-th currents supplied to first through N-th Peltier devices mounted on rear surfaces of said first through said N-th pushers so that the first through the N-th detected temperatures are equal to the first through the N-th set temperatures, respectively.

12. A method of screening first through N-th target devices, where N represents a positive integer which is not less than two, said method comprising:
pushing said first through said N-th target devices by first through N-th pushers, respectively, so as to insert said first through said N-th target devices in first through N-th sockets of an integrated circuit (IC) tester, respectively;
individually controlling the temperatures of said first through said N-th target devices so as to maintain first through N-th set temperatures, respectively;
carrying out functional tests of said first through said N-th target devices by said IC tester;
pulling out said first through said N-th target devices from said first through said N-th sockets, respectively, after end of the functional tests; and
screening said first through said N-th target devices on the basis of test results of said IC tester.

13. The method as claimed in claim 12, wherein said individually controlling the temperatures of said first through said N-th target devices comprising:
detecting the temperatures of said first through said N-th target devices to produce first through N-th detected signals indicative of first through N-th detected temperatures; and
controlling, on the basis of the first through the N-th detected signals. first through N-th currents supplied to first through N-th Peltier devices mounted on rear surfaces of said first through said N-th pushers so that the first through the N-th detected temperatures are equal to the first through the N-th set temperatures, respectively.
